(19) United States
(12) Patent Application Publication
(10) Pub. No.: US 2007/0008011 A1
(43) Pub. Date: Jan. 11, 2007

(54) Distributed power and clock management in a computerized system

(76) Inventor: Paulette Thurston, Portland, OR (US)

Correspondence Address: SCHWEGMAN, LUNDBERG, WOESSNER & KLUTH, P.A., P.O. BOX 2938, MINNEAPOLIS, MN, 55402, US

(21) Appl. No.: 11/170,770

(22) Filed: Jun. 29, 2005

(51) Int. Cl. H03K 19/00

(52) U.S. Cl. 326/93

(57) ABSTRACT

A computer circuit includes a plurality of digital logic circuits, each having a locally regulated voltage supply and a clock. The clock and locally regulated voltage supply of each of the plurality of digital logic circuits are operable to vary under control of a common power controller. A synchronizer coupled to each of the plurality of digital logic circuits, and each synchronizer is operable to synchronize the exchange of data with at least one other digital logic circuit.

### TECHNICAL FIELD

This matter relates generally to computerized system power management, and more specifically to distributed clock and power management in a computerized system.

### BACKGROUND

A wide variety of devices, including personal digital assistants, cellular telephones, and appliances now incorporate sophisticated processors, monitors or displays, and other elements once found only in expensive computers. Incorporation of processors has enabled cellular telephones to do more than just serve as a telephone—it is now common for such cell phones to include phone directories, digital cameras, music playback, video games, and to offer a high degree of programmability or customization to the cell phone end user or service provider. Similarly, personal digital assistants, or PDAs, commonly include software including calendar, e-mail, word processing, and other traditional computer functions.

But, while traditional computers are usually plugged in to a wall socket or outlet that provides electric power on a continuous basis, many portable devices such as cell phones and PDAs are powered by rechargeable batteries incorporated into the electronic computerized device. This limits the amount of time one can use such a portable device to the amount of time the rechargeable battery can provide adequate power to operate the device. One could simply use bigger batteries in situations where long-lasting operation was desirable, but battery size and performance is often traded off for smaller overall device size, lighter weight, and lower cost.

Engineers have addressed this issue by developing electronic devices that require less power to operate, or that can operate at reduced speed to conserve power. Such methods are also sometimes employed in other systems such as normal desktop computers and laptop computers, particularly where significant power savings can be realized. But, distribution of a variety of power signals and a common clock signal to a variety of modules in a computerized system can become difficult to configure and manage. Also, the delays involved with starting up a module and locking a phase-locked loop (PLL) clock receiver onto a received clock signal are significant, and reduce the opportunities to shut a module down temporarily to save power. Startup time also has a negative impact on perceived responsiveness or performance of a module that needs to restart and synchronize a PLL with a common clock.

It is therefore desirable that computerized devices have improved power and clock management.

### BRIEF DESCRIPTION OF THE FIGURES

FIG. 1 is a block diagram of a system employing distributed central clock and regulated voltage signals, consistent with the prior art.

FIG. 2 is a block diagram of a system comprising logic circuits with locally generated clock signals and locally regulated voltage signals, consistent with an example embodiment of the invention.

FIG. 3 is a flowchart illustrating a method of practicing an example embodiment of the invention.

FIG. 4 is a detailed block diagram of a computer system employing a distributed central clock and central voltage regulation, consistent with the prior art.

FIG. 5 is a detailed block diagram of a computer system comprising logic circuits having locally generated clock signals and locally regulated power signals, consistent with an example embodiment of the invention.

### DETAILED DESCRIPTION

In the following detailed description of example embodiments, reference is made to specific examples by way of drawings and illustrations. These examples are described in sufficient detail to enable those skilled in the art to practice the invention, and serve to illustrate how the invention may be applied to various purposes or embodiments. Other embodiments may be utilized and derived therefrom, such that structural and logical substitutions and changes may be made without departing from the scope of this patent application. Features or limitations of various embodiments described herein, however essential to the example embodiments in which they are incorporated, do not limit the invention as a whole, and any reference to the invention, its elements, operation, and application do not limit the invention as a whole but serve only to define these example embodiments. The following detailed description does not, therefore, limit the scope of the patent application, which is defined only by the appended claims.

The examples presented here serve to illustrate how a voltage supply and clock can be managed in digital logic circuits such as a computer to conserve energy. In various embodiments, multiple digital logic circuits each have a locally regulated voltage supply and a clock. The clock and locally regulated voltage supply of each of the plurality of digital logic circuits are operable to vary under control of a common power controller. A synchronizer coupled to each of the plurality of digital logic circuits, and each synchronizer is operable to synchronize the exchange of data with at least one other digital logic circuit. The power controller is operable to manage the voltage supply and clock local to each of the digital logic circuits based on the operation or performance required from each logic circuit. Clocks local to each logic circuit enable the circuit to begin operation much more quickly than would be possible using a central distributed clock system in which a phase locked loop local to the logic circuit would need to lock on to the central clock signal before logic circuit operation.

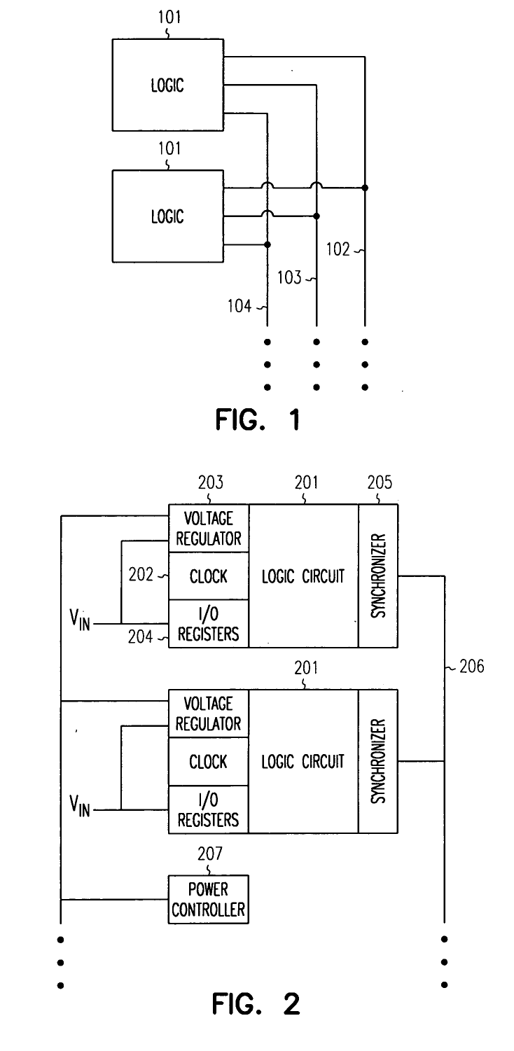

FIG. 1 shows a digital logic system having a common clock and power supply, consistent with the prior art. Multiple logic circuits 101, such as functional units within a processor, peripheral devices, integrated circuits, or other logical elements are coupled by a data channel or bus 102. The logic circuits are further driven by a clock signal carried to each logic circuit element by a clock signal distribution network 103. Power is supplied by one or more voltage supply networks 104, which in some embodiments includes voltage networks for multiple voltages such as 5V, 3.3V, 1.5V, or other common supply voltages.

Power consumption is managed by reducing the clock rate or voltage supplied to the logic circuits 101, under the management of a power controller. The clock can be reduced in speed for all logic circuits, or reduced via a clock divider circuit at individual logic circuits facing relatively low performance demands. It can also be disconnected entirely by means of a switch such as a transistor that is operable to disconnect a logic circuit from the clock when not needed. This effectively stops the clock and stops power loss due to switching the state of transistors and other devices in the logic circuit, but leakage current still remains as a power drain in the logic circuit.

In logic circuits where the present state need not be retained, the voltage supplied can be cut off entirely by way of gating or switching the power signal with transistors, thereby reducing the leakage current consumed. This causes the circuit to consume very little or no power, but results in a restart time that is long enough to make a complete power down impractical in many situations.

When the clock signal supplied is gated or switched, a phase-locked loop (PLL) circuit typically continues to track the received clock signal, drawing power by its operation. When the voltage is turned off entirely, the phase-locked loop must restart and re-acquire or lock on to the clock signal distributed from the master clock via the clock distribution network 103, which can take 30 microseconds or more even for relatively fast on-die PLL circuits.

Some embodiments of the invention seek to solve the problem of slow resumption of clocked logic operation by using a locally generated clock and a locally regulated voltage for each of two or more logic circuits in a system. FIG. 2 shows a block diagram of such a system employing a number of logic modules employing local clock and voltage regulation, coupled via local synchronizers to a bus. Each of two or more logic circuits 201 has its own local clock 202 and voltage regulator 203. In further embodiments, a second voltage connection 204 is used to power input and output (I/O) circuitry, as well as to power registers operable to retain the state of the logic circuit when the logic circuit is powered down. The logic circuits are coupled via a synchronizer 205 to a bus 206, such that the various logic circuits using independent local clocks 202 can exchange data with one another.

In operation, a power controller 207 manages the state of the clocks 202 and the voltage regulators 203 of the logic circuits 201. The voltage level and clock speed in some embodiments are varied separately or together to change the power consumption and performance capabilities of the local logic circuit, such as running at an elevated voltage and maximum clock rate to provide maximum performance or running at a fraction of the normal clock speed and a reduced voltage to conserve power when maximum performance is not needed. In some embodiments, the minimum allowable voltage is dependent on the frequency, as higher voltages are required to operate at increasingly high frequencies. The order of voltage and frequency change is further controlled in some embodiments, such that a voltage is reduced after a frequency decline but before a frequency increase to ensure sufficient voltage for proper operation remains present during transitions.

The clock signal is generated locally in part so that it can resume normal operation more quickly than a PLL clock receiver would be able to lock on to a distributed clock. A typical on-die PLL clock needs approximately 30 microseconds to stably lock on to a received clock signal, while a local clock can start and operate at a stable frequency in under 100 nanoseconds. Because clock resumption is currently approximately 300 times faster than locking on to a received clock signal, the clock, and the attached digital logic circuit, can restart much more quickly using a local clock than by receiving a distributed clock.

This is significant for power management purposes, as the ability of a circuit to shut down and restart quickly influences the practicality of shutting down and restarting the circuit in many situations where the digital logic circuit is idle for only a brief period of time. For example, if a video processor is rendering moving graphics and has an average of 100 microseconds of inactive time between rendered frames, it may not be worthwhile to shut down and restart the video processor during the inactive 100 microsecond period considering the restart time of 30 microseconds or greater. But, if the restart time is reduced to 100 nanoseconds, the power savings can become significant.

Voltage regulation local to the digital logic circuit allows the voltage to be altered locally and quickly along with the clock frequency, and simplifies circuit board layout where multiple digital logic voltages would previously have been routed to provide all needed voltages to the digital logic circuits in a system. Previous solutions to power management included gating a voltage so that the power to any specific digital logic circuit could be shut off and turned back on quickly, and altering the voltage level of a distributed voltage signal so that all circuits using the distributed voltage signal operated at the altered voltage. Distribution of voltage regulation to digital logic circuits enables each digital logic circuit to operate at a voltage deemed most appropriate for that circuit, and complements the ability to locally generate the clock signal so that each circuit is able to operate at a voltage and clock frequency most appropriate for the circuit's operation.

Because the digital logic circuits having local clocks and voltage regulation will likely not be operating in clock synchronization with each other, exchange of data is managed in some embodiments by use of a synchronizer 205 attached to each digital logic circuit. The synchronizers are operable to couple the logic circuit to another logic circuit, to another synchronizer, or to a bus that enables a variety of circuits to exchange data such as is common in a personal computer. The synchronizer in some embodiments includes at least one data buffer to store data, and a circuit operable to receive data from a circuit operating at a first clock frequency, store it in a buffer, and send the buffered data to a circuit operating at a second clock frequency that may not be the same frequency or in synchronization with the first clock signal.

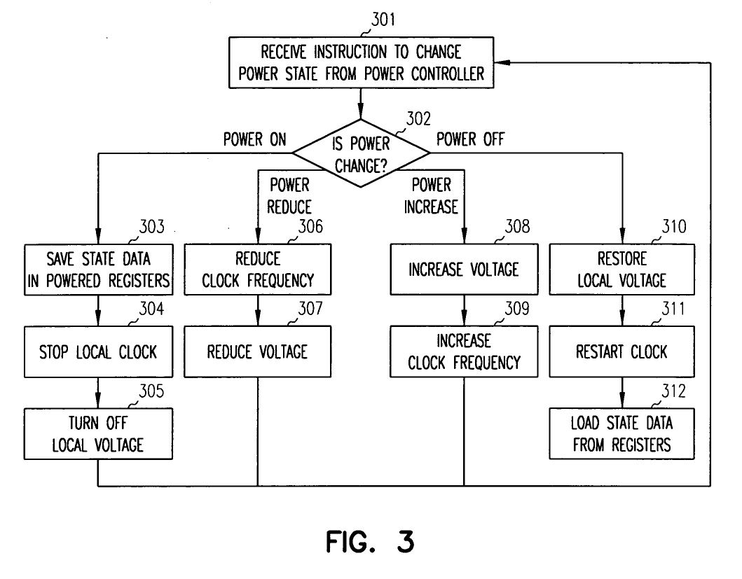

FIG. 3 is a flowchart of a method of operating a digital logic circuit, consistent with an example embodiment of the invention. At 301, an instruction is received such as from a power controller to change the power state of a logic circuit having its own local clock and voltage regulator. At 302, the change is determined to be either a power off, a power on, a power increase, or a power decrease.

If the power change is a power off, the state of various elements within the digital logic circuit are saved in registers powered by a power supply other than the locally regulated voltage supply at 303, so that the state of the circuit can be retained while the power is off. At 304, the local clock is stopped, and the local voltage is turned off at 305. The logic circuit then returns to 301, waiting for a power on or other such power mode signal indicating it should return to an operative state.

If the power change is a power reduction, the clock frequency is reduced at 306, and the voltage is subsequently reduced at 307. Reducing the voltage after reducing the clock frequency ensures that the logic circuit has sufficient voltage to operate while transitioning to the lower clock frequency, and is significantly easier to implement than changing the voltage and the clock rate simultaneously.

If the power mode change is a power increase, the locally regulated voltage signal is restored to the logic circuit at 308, and the clock frequency is increased at 309. Again, the voltage is changed at a time such that sufficient voltage is always present in the logic circuit during the frequency change. By increasing the voltage at 308 before increasing the frequency at 309, sufficient voltage will be present in the digital logic circuit throughout the change to ensure proper logic operation.

If the power mode change is a power on, recovering from a power off state, the locally regulated voltage supplied to the logic circuit is restored at 310. The clock is restarted at 311, and the state of the logic circuit at shutdown is loaded from the registers at 312. Power to the registers is not cut when the local logic circuit is powered off, so the registers are able to retain the logic state of the logic circuit and facilitate a quick logic circuit restart.

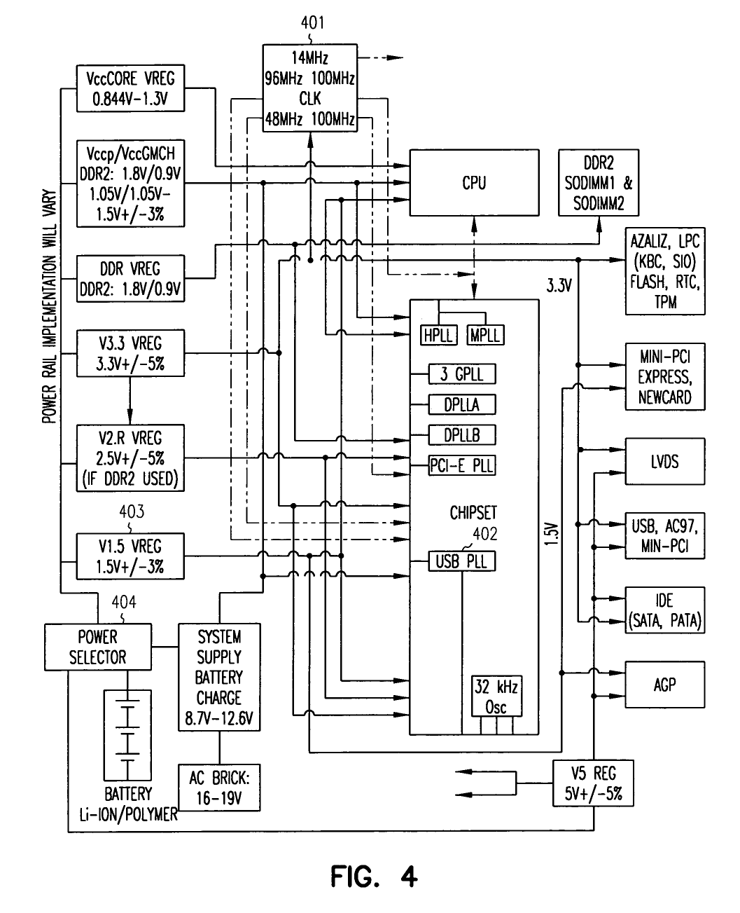

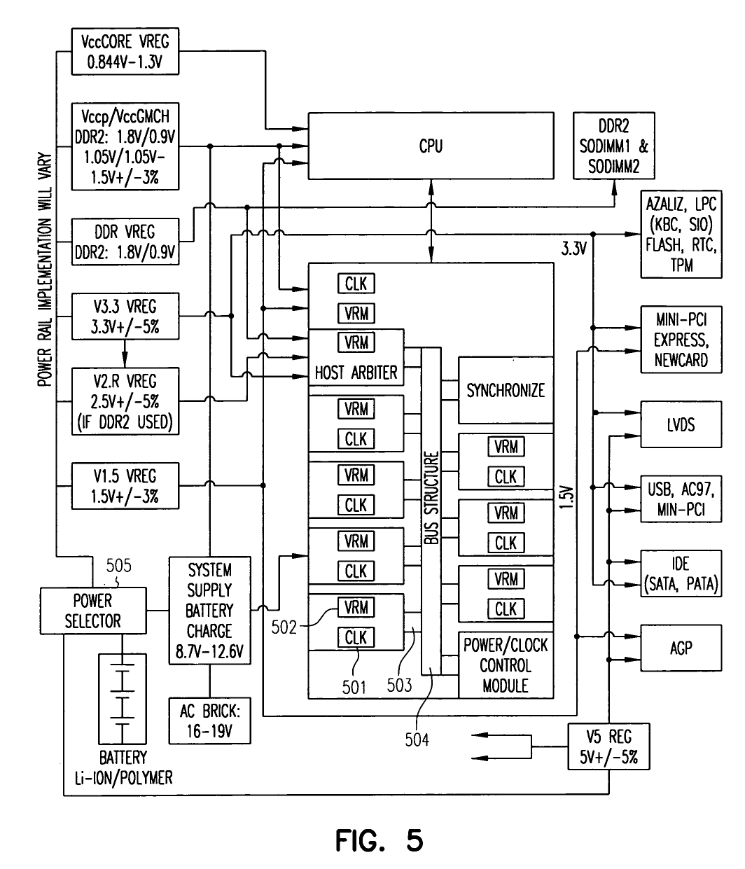

After each of the power mode changes, the circuit operates or remains powered off in the selected power state until the power state of the local logic circuit is again changed, or until the system or device of which the logic circuit is a part is powered off. FIGS. 4 and 5 show how a typical computerized system can benefit from distributed clock, voltage regulation, and interface synchronization. In FIG. 4, a master clock 401 is distributed to various logic circuits within the chipset combo integrated circuit, and to other circuits such as the CPU. A phase-locked loop (PLL) clock receiver 402 receives the appropriate clock signal, and locks onto it so that the USB circuit within the chipset can operate in synchronization with the rest of the computer system. Power is supplied via an external voltage regulator 403, and is managed by the power controller or power selector 404. The power controller is operable to change which clock frequency is provided to a logic circuit such as the USB logic circuit, and to control whether a particular circuit receives power from an external voltage regulator or is gated so that power is cut off.

FIG. 5, in contrast, uses a clock 501 that is local to each logic circuit element, and includes a local voltage regulator 502 and synchronization module 503 operable to facilitate communication with other logic circuits via a bus 504. The clock frequency generated by clock 501 and the regulated voltage generated by voltage regulator 502 are controlled via the power controller or power selector 505, which is able to independently vary the clock speed and operating voltage of the various logic circuit elements in a system such as that of FIG. 5.

Circuit configurations having independent voltage regulators and clock modules reduce the need to route multiple clock signals, as are shown in FIG. 4, and enables the use of a greater number of voltages and clock frequencies throughout an electronic system. The thermal impact on integrated circuits such as the chipset combo integrated circuit of FIGS. 4 and 5 is also significant, as certain portions of the chip can be powered off completely when not used, saving heat and power dissipated from leakage current that is present in a circuit even when the clock signal is stopped.

Consider as an example a cellular telephone having the ability to allow a user to play games, read e-mail, and perform other functions in addition to typical cellular phone functions. When a user switches from playing a video game to reading e-mail, memory access decreases sharply, and display processing demand decreases significantly. The clock signal and the voltage to the display or graphics processor can therefore likely be decreased significantly, and the memory controller can likely be powered off and restarted on occasion as new data is loaded from memory. The power savings from reducing the operating frequency and voltage of a logic circuit under only moderate demand and temporarily powering off a logic circuit while in an idle state can result in significant power savings, extending the battery life and reducing the heat generated within an electronic device.

The power modes in the various digital logic circuit examples include transition from a high power mode to a low power mode and from a low power mode to a high power mode, which in some embodiments are transitions between two of many different power modes. In a specific cellular phone example, a normal mode, idle mode, deep idle mode, standby mode, sleep mode, and deep sleep mode are all supported by the power management controller. Normal mode is a state in which a logic circuit is fully powered and functional, and the local clock is running at a normal speed. In idle mode, the clock local to the digital logic circuit is substantially reduced in frequency, and the clock is brought back to a substantially higher speed through a hardware control signal such as a hardware interrupt. Deep idle mode is entered only after the logic circuit's clock frequency has been set to a frequency substantially lower than its normal operating frequency, and the local clock is typically stopped until resumption is triggered by a hardware event.

Standby mode further involves placing a significant number of power domains or logic circuits into a low power mode where state is retained but no activity is allowed. The clock sources in the individual logic circuits are typically disabled, and internal or external events such as actuation of a button trigger a wake-up to a higher power state. The low power mode in which state is retained in some embodiments includes reduction of a voltage supplied to the circuit under control to a voltage level lower than operating voltage, but higher than a zero voltage level. The voltage level is sufficient to keep the transistors of the logic circuits in their present states, but not sufficient to enable full operation of the digital logic circuits. In alternate embodiments, logic circuit state data is stored in registers that remain powered while the remainder of the logic circuit is powered down.

In sleep mode, nearly all power domains or logic circuits are powered off, including those internal to the processor other than clock and oscillator circuits used by the power manager and real time clock. Because core elements of the processor such as the pipeline, registers, and program counter are invalid after being powered down completely, resuming operation requires rebooting the cellular phone.

A further low power mode known as deep sleep mode is also employed in a further embodiment, which is essentially the same as sleep mode but in which the cell phone's states are maintained by the backup battery rather than by the main system battery or external power source. This mode is used, for example, when the phone is programmed and packaged for delivery to the end user, and may not have a main system battery attached.

These modes serve to illustrate how various logic circuit elements, whether internal or external to the processor, can be managed in various power states using locally regulated voltages and locally generated clock signals.

The examples presented here illustrate how use of a clock, voltage regulator, and synchronizer local to a digital logic circuit in an electronic device enable the circuit's power consumption and heat dissipation to be more efficiently managed than is possible with traditional distributed master clock and voltage systems. Although specific embodiments have been illustrated and described herein, it will be appreciated by those of ordinary skill in the art that any arrangement which is calculated to achieve the same purpose may be substituted for the specific embodiments shown. This application is intended to cover any adaptations or variations of the example embodiments of the invention described herein. It is intended that the scope of this matter be limited only by the claims, and the full scope of equivalents thereof.

1. A computer circuit, comprising:
a plurality of digital logic circuits, each having a locally regulated voltage supply and a clock, the clock frequency of two or more local clocks and the voltage of two or more locally regulated voltage supplies adjustable under control of a common power controller; and
a synchronizer coupled to each of the plurality of digital logic circuits, each synchronizer operable to synchronize the exchange of data with at least one other digital logic circuit.

2. The computer circuit of claim 1, wherein the plurality of digital logic circuits are on the same integrated circuit.

3. The computer circuit of claim 1, wherein at least one of the plurality of digital logic circuits further comprises one or more registers operable to retain data while the digital logic circuit's voltage is reduced such that the digital logic circuit is inoperable.

4. The computer circuit of claim 1, wherein at least two of the plurality of digital logic circuits are coupled via their respective synchronizers by a bus.

5. The computer circuit of claim 1, wherein the plurality of logic circuits comprise functional units within a processor.

6. The computer circuit of claim 5, wherein the processor is a multi-core processor.

7. The computer circuit of claim 1, wherein at least two of the plurality of logic circuits comprise peripheral device logic within a computerized system.

8. A method of managing a plurality of digital logic circuits in an electronic system, comprising:
controlling the voltage provided from voltage regulators local to each of the plurality of digital logic circuits;
controlling the frequency of a clock signal generated local to each of the plurality of digital logic circuits; and
synchronizing exchange of data between at least two of the plurality of digital logic circuits via a synchronizer in at least two of the plurality of digital logic circuits

9. The method of claim 8, wherein the plurality of digital logic circuits are on the same integrated circuit.

10. The method of claim 8, further comprising retaining logic circuit state data in registers powered sufficiently to retain their states for at least one of the plurality of digital logic circuits when in a reduced voltage mode such that the digital logic circuit is inoperable.

11. The method of claim 8, wherein at least two of the plurality of digital logic circuits are coupled via their respective synchronizers by a bus.

12. The method of claim 8, wherein the plurality of logic circuits comprise functional units within a processor.

13. The method of claim 12, wherein the processor is a multi-core processor.

14. The method of claim 8, wherein at least two of the plurality of logic circuits comprise peripheral device logic within a computerized system.

15. An electronic system, comprising:
a plurality of digital logic circuits, each having a locally regulated voltage supply and a clock;
a power controller operable to control the clock and regulated voltage supply local to each of the plurality of digital logic circuits;
a battery operable to power the plurality of digital logic circuits; and
a synchronizer coupled to each of the plurality of digital logic circuits, each synchronizer operable to synchronize the exchange of data with at least one other digital logic circuit.

16. The electronic system of claim 15, wherein the plurality of digital logic circuits are on the same integrated circuit.

17. The electronic system of claim 15, wherein at least one of the plurality of digital logic circuits further comprises one or more registers operable to retain data while the digital logic circuit's voltage is reduced such that the digital logic circuit is inoperable.

18. The electronic system of claim 15, wherein at least two of the plurality of digital logic circuits are coupled via their respective synchronizers by a bus.

19. The electronic system of claim 15, wherein the plurality of logic circuits comprise functional units within a processor.

20. The electronic system of claim 19, wherein the processor is a multi-core processor.

21. The electronic system of claim 15, wherein at least two of the plurality of logic circuits comprise peripheral device logic within a computerized system.

22. The electronic system of claim 15, wherein the device comprises a cell phone, a personal digital assistant, a gaming system, or a portable computer.

23. A logic circuit, comprising:
a regulated voltage supply operable to provide a regulated voltage to the logic circuit;
a clock operable to provide a local clock signal to the logic circuit;
a power controller interface operable to receive a control signal for controlling the regulated voltage supply voltage and the clock frequency; and
a synchronizer interface operable to synchronize data exchange with at least one other digital logic circuit having separate clocks and regulated voltage supplies.

24. The logic circuit of claim 23, wherein the plurality of digital logic circuits are on the same integrated circuit.

25. The logic circuit of claim 23, wherein at least one of the plurality of digital logic circuits further comprises one or more registers operable to retain data while the digital logic circuit's voltage is reduced such that the digital logic circuit is inoperable.

26. The logic circuit of claim 23, wherein at least two of the plurality of digital logic circuits are coupled via their respective synchronizers by a bus.

27. The logic circuit of claim 23, wherein the plurality of logic circuits comprise functional units within a processor.

28. The logic circuit of claim 27, wherein the processor is a multi-core processor.

29. The logic circuit of claim 23, wherein at least two of the plurality of logic circuits comprise peripheral device logic within a computerized system.
